(19) United States
(12) Patent Application Publication
(10) Pub. No.: US 2026/0353614 A1
(43) Pub. Date: Nov. 5, 2026

(54) SYSTEMS AND METHODS FOR POWER OPTIMIZATION USING REAR-DOOR HEAT EXCHANGER

(71) Applicant: Dell Products L.P., Round Rock, TX (US)

(72) Inventors: Michael L. HOBBS, Austin, TX (US); Kyle E. CROSS, Austin, TX (US); Douglas E. MESSICK, Austin, TX (US); Aaron M. RHINEHART, Georgetown, TX (US); Binay A. KURUVILA, Cedar Park, TX (US); Mohammed K. HIJAZI, Austin, TX (US); Thomas F. ARCHER, Austin, TX (US)

(73) Assignee: Dell Products L.P., Round Rock, TX (US)

(21) Appl. No.: 19/198,296

(22) Filed: May 5, 2025

(51) Int. Cl. H05K 7/20

(52) U.S. Cl. CPC H05K 7/20836; H05K 7/20736

(57) ABSTRACT

A cabinet may include a rack configured to house one or more information handling systems, a door mechanically coupled to the rack and comprising a rear-door heat exchanger and a cabinet-level thermal control subsystem configured to, based on power consumption metrics of the rack, the one or more information handling systems, and the heat exchanger, determine whether to override speeds for one or more air movers of the heat exchanger as determined by a thermal control loop of the heat exchanger, in response to determining to override, alter the speeds for the one or more air movers from those determined by the control loop in order to minimize aggregate power consumption among components of the cabinet, and in response to determining to not override, allow the thermal control loop of the heat exchanger to control speeds of the one or more air movers unaltered by the cabinet-level thermal control subsystem.

### TECHNICAL FIELD

The present disclosure relates in general to information handling systems, and more particularly to systems and methods for implementing a closed loop algorithm for a rear-door heat exchanger that minimizes power consumption within a server rack.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, thermal management systems including air movers (e.g., cooling fans and blowers) and liquid cooling systems have often been used in information handling systems to cool information handling systems and their components. Some thermal management systems utilize air movers and liquid-cooled heat exchangers (e.g., a radiator with liquid-cooled cooling coils).

Further, information handling systems may be housed in a cabinet configured to hold a plurality of modular information handling systems and other components, such as air movers and liquid-cooled heat exchangers. In some cabinets, a liquid-cooled heat exchanger and air mover unit may be integrated within a service door at the rear of the server rack, wherein such door may be accessed for servicing components residing within the cabinet.

The heat exchanger that resides within the service door may be known as a rear-door heat exchanger. One side effect of a rear-door heat exchanger is that it may pull additional airflow through the cabinet in addition to that provided by air movers internal to the cabinet. Further, in existing approaches, a thermal control loop of the rear-door heat exchanger and thermal control loop of the information technology (IT) gear (e.g., information handling systems) internal to the cabinet may be completely independent from each other, although the rear-door heat exchanger may provide additional cooling to the IT gear. While thermal control loops of IT gear may be based on thermal conditions within the IT gear, air mover control of the rear-door heat exchanger may be based on thermal exhaust of the rear-door heat exchanger, and maintaining a negative pressure behind the IT gear and liquid cooling flow control may be based on exhaust temperature. Thus, in existing approaches, the IT gear and the rear-door heat exchanger have independent control solutions that may not work together to minimize power consumption while providing sufficient cooling.

### SUMMARY

In accordance with the teachings of the present disclosure, disadvantages and problems associated with existing cabinets housing information handling systems may be reduced or eliminated.

In accordance with embodiments of the present disclosure, a cabinet may include a rack configured to house one or more information handling systems, a door mechanically coupled to the rack and comprising a rear-door heat exchanger and a cabinet-level thermal control subsystem configured to, based on power consumption metrics of the rack, the one or more information handling systems, and the rear-door heat exchanger, determine whether to override speeds for one or more air movers of the rear-door heat exchanger as determined by a thermal control loop of the rear-door heat exchanger, in response to determining to override, alter the speeds for the one or more air movers from those determined by the control loop in order to minimize aggregate power consumption among components of the cabinet, and in response to determining to not override, allow the thermal control loop of the rear-door heat exchanger to control speeds of the one or more air movers unaltered by the cabinet-level thermal control subsystem.

In accordance with these and other embodiments of the present disclosure, a method may include, in a cabinet having a rack configured to house one or more information handling systems, a door mechanically coupled to the rack and comprising a rear-door heat exchanger, based on power consumption metrics of the rack, the one or more information handling systems, and the rear-door heat exchanger, determining whether to override speeds for one or more air movers of the rear-door heat exchanger as determined by a thermal control loop of the rear-door heat exchanger, in response to determining to override, altering the speeds for the one or more air movers from those determined by the control loop in order to minimize aggregate power consumption among components of the cabinet, and in response to determining to not override, allowing the thermal control loop of the rear-door heat exchanger to control speeds of the one or more air movers unaltered by the cabinet-level thermal control subsystem.

In accordance with these and other embodiments of the present disclosure, an article of manufacture may include a non-transitory computer-readable medium and computer-executable instructions carried on the computer-readable medium, the instructions readable by a processor, the instructions, when read and executed, for causing the processor to, in a cabinet having a rack configured to house one or more information handling systems, a door mechanically coupled to the rack and comprising a rear-door heat exchanger, based on power consumption metrics of the rack, the one or more information handling systems, and the rear-door heat exchanger: determine whether to override speeds for one or more air movers of the rear-door heat exchanger as determined by a thermal control loop of the rear-door heat exchanger; in response to determining to override, alter the speeds for the one or more air movers from those determined by the control loop in order to minimize aggregate power consumption among components of the cabinet; and in response to determining to not override, allow the thermal control loop of the rear-door heat exchanger to control speeds of the one or more air movers unaltered by the cabinet-level thermal control subsystem.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example cabinet for housing a plurality of information handling systems, in accordance with embodiments of the present disclosure; and

FIGS. 2A-2C (which may be referred to herein collectively as “FIG. 2”) illustrate a flow chart of an example method for power optimization of components of a cabinet using a rear-door heat exchanger of the cabinet, in accordance with embodiments of the present disclosure.

### DETAILED DESCRIPTION

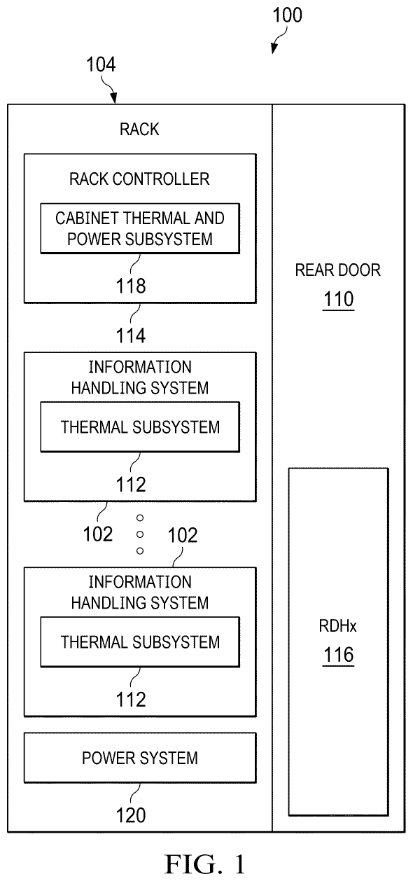

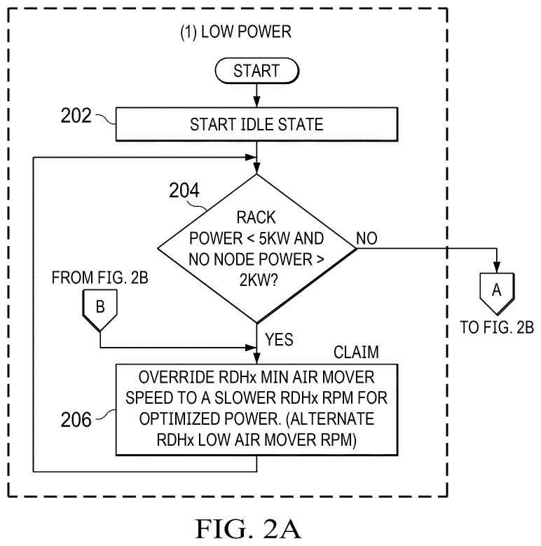

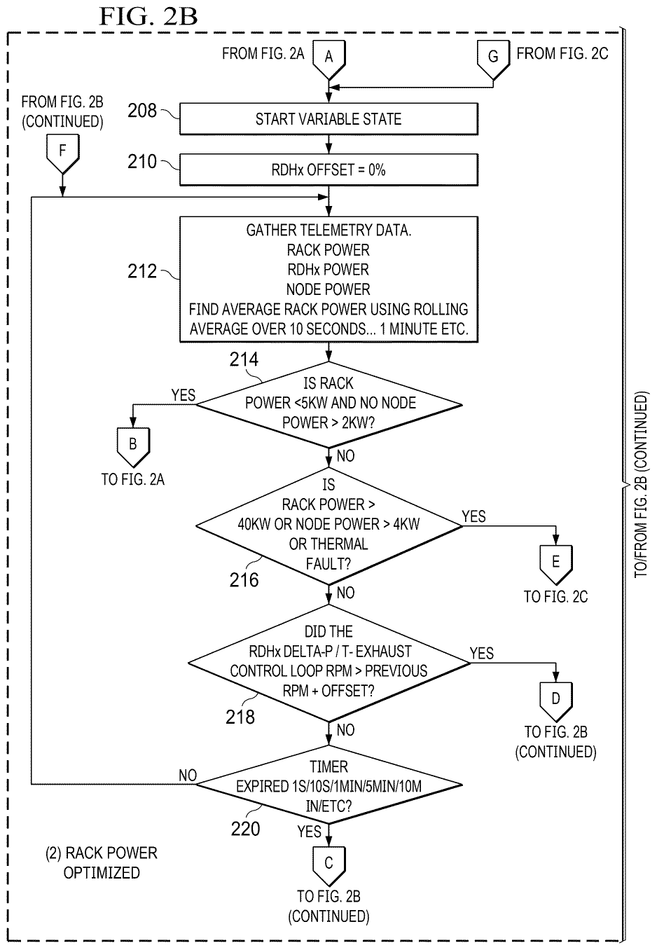

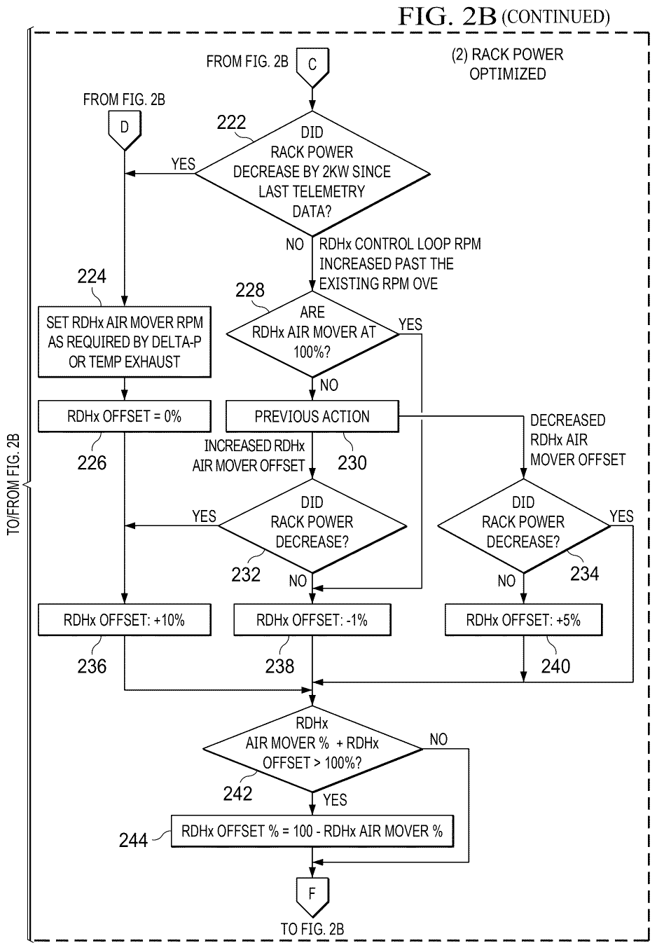

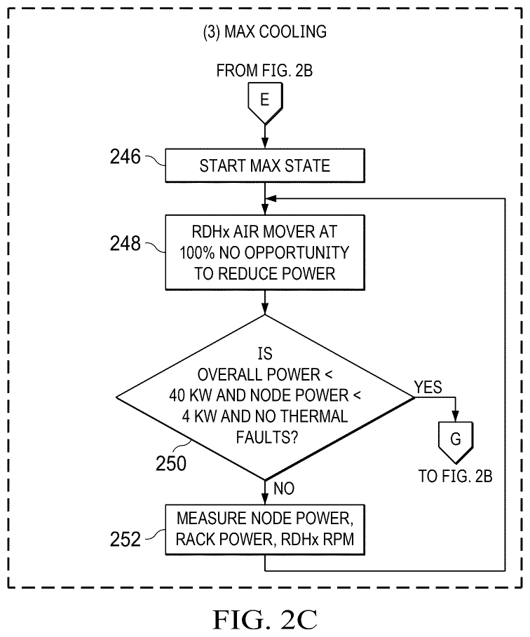

Preferred embodiments and their advantages are best understood by reference to FIGS. 1 through 2C, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example cabinet 100 for housing a plurality of information handling systems, in accordance with embodiments of the present disclosure. As shown in FIG. 1, cabinet 100 may comprise a rear door 110 mechanically coupled to rack 104. Rack 104 may comprise a plurality of vertically-stacked slots (not explicitly shown) configured to accept information handling systems 102 and a power system 120 that may include one or more power supplies that provide electrical energy to the information handling systems 102. Rack 104 may also be referred to as a housing, enclosure, chassis, or other appropriate term.

As shown in FIG. 1, each information handling system 102 may include a thermal subsystem 112. A thermal subsystem 112 may include one or more components for cooling components of its respective information handling system 102, including without limitation one or more air movers for driving airflow across components of such information handling system 102 and a control subsystem for controlling (e.g., via closed loop control) the one or more air movers.

Further, rear door 110 may have inset therein a cooling subsystem which may also be referred to as a rear-door heat exchanger (RDHx) 116. RDHx 116 may include one or more components for cooling components of cabinet 100, including without limitation one or more air movers for driving airflow within cabinet 100, one or more radiator coils for transferring heat from air flowing proximate to the one or more radiator coils to liquid (e.g., water) flowing through the one or more radiator coils, and a control subsystem for controlling (e.g., via closed loop control) the one or more air movers and controlling a flow of the liquid of RDHx 116.

As shown in FIG. 1, rack 104 may also include a rack controller 114. Rack controller 114 may comprise an information handling system, and may be configured to perform monitoring, control, and management of information handling systems 102 and/or other components of rack 104. As shown in FIG. 1, rack controller 114 may also include a cabinet thermal and power subsystem 118.

Cabinet thermal and power subsystem 118 may include any system, device, or apparatus configured to further control (e.g., via closed loop control) by selectively overriding, when certain conditions exist within cabinet 100 (e.g., based on power consumption within rack 104), the control subsystem of RDHx 116 with an alternate control algorithm for RDHx 116, as described in greater detail below.

FIG. 2 illustrates a flow chart of an example method 200 for power optimization of components of cabinet 100 using RDHx 116, in accordance with embodiments of the present disclosure. According to certain embodiments, method 200 may begin at step 202. As noted above, teachings of the present disclosure may be implemented in a variety of configurations of cabinet 100. As such, the preferred initialization point for method 200 and the order of the steps comprising method 200 may depend on the implementation chosen.

At step 202, cabinet thermal and power subsystem 118 may undertake operation in an idle state. At step 204, cabinet thermal and power subsystem 118 may determine if power consumption by cabinet 100 is below an associated threshold (e.g., 5 KW) and if the power consumption of all nodes (e.g., information handling system 102) is below an associated threshold (e.g., 2 KW). If both of these conditions are satisfied, the power consumption within cabinet 100 and information handling systems 102 may be low enough that operation of air movers of RDHx 116 are not needed. Thus, if both of these conditions are satisfied, method 200 may proceed to step 206. Otherwise, if either or both conditions are unsatisfied, method 200 may proceed to step 208.

At step 206, cabinet thermal and power subsystem 118 may cause operation in a low power mode, in which power consumption may be optimized by overriding the control subsystem of RDHx 116 to cause the air movers of RDHx 116 to operate at a slower speed than they would in the absence of the override of the control subsystem of RDHx 116. After completion of step 206, method 200 may proceed again to step 204.

At step 208, cabinet thermal and power subsystem 118 may begin operation in a variable state and a rack-power optimized mode. At step 210, cabinet thermal and power subsystem 118 may set an RDHx offset value to 0%.

At step 212, cabinet thermal and power subsystem 118 may gather telemetry data including power consumption by RDHx 116, rack 104, and information handling systems 102. In some embodiments, cabinet thermal and power subsystem 118 may determine averages for each of these levels of power consumption (e.g., a 10-second rolling average, 1-minute rolling average, etc).

At step 214, cabinet thermal and power subsystem 118 may determine if power consumption by cabinet 100 is below an associated threshold (e.g., 5 KW) and if no node (e.g., information handling system 102) has a power consumption greater than an associated threshold (e.g., 2 KW). If both of these conditions are met, method 200 may proceed again to step 206. If one or both of these conditions are not met, method 200 may proceed to step 216.

At step 216, cabinet thermal and power subsystem 118 may determine if power consumption by cabinet 100 is above an associated threshold (e.g., 40 KW), if the power consumption by any node (e.g., information handling system 102) is above an associated threshold (e.g., 4 KW), or if a thermal fault exists within rack 104. Examples of thermal faults may include server air mover failure, a temperature limit exceeded, loss of telemetry information from a temperature-sensitive component, alerts asserted by a device, etc. If any of these conditions are met, method 200 may proceed to step 246. Otherwise, if none of these conditions are met, method 200 may proceed to step 218.

At step 218, cabinet thermal and power subsystem 118 may determine if the air mover speed for RDHx 116 needs to be increased above a sum of the previous air mover speed for RDHx 116 plus the RDHx offset value, based on the RDHx pressure delta and/or a thermal exhaust control loop. If such condition is met, method 200 may proceed to step 224. Otherwise, if such condition is not met, method 200 may proceed to step 220.

At step 220, cabinet thermal and power subsystem 118 may determine if a timer has expired. If the timer has expired, method 200 may proceed to step 222. If the timer remains unexpired, method 200 may proceed again to step 212.

At step 222, cabinet thermal and power subsystem 118 may determine if power consumption by cabinet 100 decreased by a particular amount (e.g., 2 KW) since the last telemetry data was collected. If such decrease has occurred, method 200 may proceed to step 224. Otherwise, method 200 may proceed to step 228.

At step 224, cabinet thermal and power subsystem 118 may cause speeds of the air movers of RDHx 116 to be set in accordance with that determined by the control system of RDHx 116. At step 226, cabinet thermal and power subsystem 118 may set the RDHx offset value to 0%. After the completion of step 226, method 200 may proceed to step 236.

At step 228, cabinet thermal and power subsystem 118 may determine if air movers of RDHx 116 are at their maximum speed. If air movers of RDHx 116 are at their maximum speed, method 200 may proceed to step 238. If air movers of RDHx are at less than their maximum speed, method 200 may proceed to step 230.

At step 230, cabinet thermal and power subsystem 118 may determine a previous action taken with respect to the RDHx offset value. If the previous action was an increase to the RDHx offset value, method 200 may proceed to step 232. If the previous action was a decrease to the RDHx offset value, method 200 may proceed to step 234.

At step 232, cabinet thermal and power subsystem 118 may determine if the increased RDHx offset value led to a decrease in power consumption by cabinet 100. If the increased RDHx offset value led to a decrease in power consumption by cabinet 100, method 200 may proceed to step 236. Otherwise, method 200 may proceed to step 238.

At step 234, cabinet thermal and power subsystem 118 may determine if the decreased RDHx offset value led to a decrease in power consumption by cabinet 100. If the increased RDHx offset value led to a decrease in power consumption by cabinet 100, method 200 may proceed to step 238. Otherwise, method 200 may proceed to step 240.

At step 236, cabinet thermal and power subsystem 118 may increase the RDHx offset value by 10% (or another suitable value), and apply such increased RDHx offset value to the speeds of the air movers of RDHx 116 determined by the control system of RDHx 116. After completion of step 236, method 200 may proceed to step 242.

At step 238, cabinet thermal and power subsystem 118 may decrease the RDHx offset value by 1% (or another suitable value), and apply such decreased RDHx offset value to the speeds of the air movers of RDHx 116 determined by the control system of RDHx 116. After completion of step 238, method 200 may proceed to step 242.

At step 240, cabinet thermal and power subsystem 118 may decrease the RDHx offset value by 5% (or another suitable value), and apply such increased RDHx offset value to the speeds of the air movers of RDHx 116 determined by the control system of RDHx 116. After completion of step 240, method 200 may proceed to step 242.

At step 242, cabinet thermal and power subsystem 118 may determine if the sum of the speeds of the air movers of RDHx 116 determined by the control system of RDHx 116 and the RDHx offset value is greater than 100%. If the sum of the speeds of the air movers of RDHx 116 determined by the control system of RDHx 116 and the RDHx offset value is greater than 100%, method 200 may proceed to step 244. Otherwise, method 200 may proceed again to step 212.

At step 244, cabinet thermal and power subsystem 118 may set the RDHx offset value to 100% minus the percentage of the maximum speed at which the speeds of the air movers of RDHx 116 have been set by the control system of RDHx 116. After completion of step 244, method 200 may proceed again to step 212.

At step 246, cabinet thermal and power subsystem 118 may begin operation in a max state and a max cooling mode. At step 248, the control system of RDHx 116 may cause its air movers to operate at their maximum speed.

At step 250, cabinet thermal and power subsystem 118 may determine if power consumption by cabinet 100 is below an associated threshold (e.g., 40 KW), the power consumption by all nodes (e.g., information handling systems 102) is below an associated threshold (e.g., 4 KW), and no thermal fault exist within rack 104. If all of these conditions are met, method 200 may proceed to step 208. Otherwise, method 200 may proceed to step 252.

At step 252, cabinet thermal and power subsystem 118 may gather telemetry data including power consumption by RDHx 116, rack 104, and information handling systems 102. After completion of step 252, method 200 may proceed again to step 248.

Although FIG. 2 discloses a particular number of steps to be taken with respect to method 200, method 200 may be executed with greater or fewer steps than those depicted in FIG. 2. In addition, although FIG. 2 discloses a certain order of steps to be taken with respect to method 200, the steps comprising method 200 may be completed in any suitable order.

Method 200 may be implemented using cabinet thermal and power subsystem 118, other components of cabinet 100, and/or any other system operable to implement method 200. In certain embodiments, method 200 may be implemented partially or fully in software and/or firmware embodied in computer-readable media.

Accordingly, under the additional closed loop control implemented by cabinet thermal and power subsystem 118, cabinet thermal and power subsystem 118 may minimize total power consumed within cabinet 100. Such closed loop control may decrease rack power by decreasing speeds of air movers of RDHx 116 when overall power consumption of rack 104 and information handling system 102 is low, may decrease rack power by increasing speeds of air movers of RDHx 116 based on rack-level telemetry and power telemetry of RDHx 116, and may not override speeds of air movers of RDHx 116 when maximum cooling by RDHx 116 is required within cabinet 100.

While the terms “top” and “bottom” and similar terms are used for purposes of exposition and clarity, such terms are not intended to limit any of the mounts disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A cabinet comprising:
a rack configured to house one or more information handling systems;
a door mechanically coupled to the rack and comprising a rear-door heat exchanger; and
a cabinet-level thermal control subsystem configured to, based on power consumption metrics of the rack, the one or more information handling systems, and the rear-door heat exchanger:
determine whether to override speeds for one or more air movers of the rear-door heat exchanger as determined by a thermal control loop of the rear-door heat exchanger;
in response to determining to override, alter the speeds for the one or more air movers from those determined by the control loop in order to minimize aggregate power consumption among components of the cabinet; and
in response to determining to not override, allow the thermal control loop of the rear-door heat exchanger to control speeds of the one or more air movers unaltered by the cabinet-level thermal control subsystem.

2. The cabinet of claim 1, wherein the cabinet-level thermal control subsystem is configured to decrease the aggregate power consumption by decreasing speeds of the one or more air movers when the power consumption metrics are below one or more associated thresholds.

3. The cabinet of claim 1, wherein the cabinet-level thermal control subsystem is configured to decrease the aggregate power consumption by increasing speeds of the one or more air movers based on the power consumption metrics.

4. A method comprising, in a cabinet having a rack configured to house one or more information handling systems, a door mechanically coupled to the rack and comprising a rear-door heat exchanger, based on power consumption metrics of the rack, the one or more information handling systems, and the rear-door heat exchanger:
determining whether to override speeds for one or more air movers of the rear-door heat exchanger as determined by a thermal control loop of the rear-door heat exchanger;
in response to determining to override, altering the speeds for the one or more air movers from those determined by the control loop in order to minimize aggregate power consumption among components of the cabinet; and
in response to determining to not override, allowing the thermal control loop of the rear-door heat exchanger to control speeds of the one or more air movers unaltered by the cabinet-level thermal control subsystem.

5. The method of claim 4, further comprising decreasing the aggregate power consumption by decreasing speeds of the one or more air movers when the power consumption metrics are below one or more associated thresholds.

6. The method of claim 4, further comprising decreasing the aggregate power consumption by increasing speeds of the one or more air movers based on the power consumption metrics.

7. An article of manufacture comprising:
a non-transitory computer-readable medium; and
computer-executable instructions carried on the computer-readable medium, the instructions readable by a processor, the instructions, when read and executed, for causing the processor to, in a cabinet having a rack configured to house one or more information handling systems, a door mechanically coupled to the rack and comprising a rear-door heat exchanger, based on power consumption metrics of the rack, the one or more information handling systems, and the rear-door heat exchanger:
determine whether to override speeds for one or more air movers of the rear-door heat exchanger as determined by a thermal control loop of the rear-door heat exchanger;
in response to determining to override, alter the speeds for the one or more air movers from those determined by the control loop in order to minimize aggregate power consumption among components of the cabinet; and
in response to determining to not override, allow the thermal control loop of the rear-door heat exchanger to control speeds of the one or more air movers unaltered by the cabinet-level thermal control subsystem.

8. The article of claim 7, the instructions for further causing the processor to decrease the aggregate power consumption by decreasing speeds of the one or more air movers when the power consumption metrics are below one or more associated thresholds.

9. The article of claim 7, the instructions for further causing the processor to decrease the aggregate power consumption by increasing speeds of the one or more air movers based on the power consumption metrics.
